(19) United States
(12) Patent Application Publication
(10) Pub. No.: US 2023/0337554 A1
(43) Pub. Date: Oct. 19, 2023

(54) PHASE CHANGE MATERIAL SWITCH DEVICE AND RELATED METHODS

(71) Applicant: Infineon Technologies AG, Neubiberg (DE)

(72) Inventors: Hans-Dieter Wohlmuth, München (DE); Dominik Heiss, München (DE); Valentyn Solomko, München (DE)

(21) Appl. No.: 18/130,520

(22) Filed: Apr. 4, 2023

(30) Foreign Application Priority Data
Apr. 14, 2022 (EP) 22168493.9

(51) Int. Cl. H10N 70/20; H10N 70/00; H10N 79/00

(52) U.S. Cl. CPC H10N 70/231; H10N 70/8613; H10N 79/00

(57) ABSTRACT

A phase change switch device includes a phase change material and a heater device thermally coupled to the phase change material. The heater device is configured to have a first electrical resistance in a first state where current is applied to the heater device for heating the phase change material, and have a second electrical resistance higher than the first electrical resistance in a second state outside heating phases of the heater device.

### TECHNICAL FIELD

The present application relates to phase change material (PCM) switch devices, sometimes also simply referred to as phase change switch devices, and to corresponding methods.

### BACKGROUND

The technical requirements for radio frequency (RF) applications using high frequencies, such as radar sensing and mobile communication according to the 5G standard, are increasing. In particular, switches having improved characteristics compared to state-of-the-art CMOS switches will be required to meet future demands. Phase change switches are considered as promising candidates for switching RF signals. Such phase change switches use a phase change material (PCM) which typically exhibits a higher electric conductivity in a crystalline phase state than in an amorphous phase state. By changing the phase state of the phase change material, a switch device including such a material may be switched on and off.

For example, to change the phase state from amorphous to crystalline, typically a heater is employed heating the phase change material causing crystallization. This switching on by causing crystallization is also referred to as a set operation. In the set operation, the heater is actuated in such a way that the temperature of the phase change material is above its crystallization temperature, typically about 250° C., but below the melt temperature typically in a range of 600° C. to 900° C., for example. The length of the heating pulse caused by the heater is chosen such that any amorphous portion present in the PCM can regrow into the crystalline phase state.

When switching off the switching device, also referred to as reset operation, the heater is actuated in such a way that the temperature of the PCM is raised above the melt temperature (for example above about 600° C. to 900° C.) followed by a comparatively rapid cooldown which freezes the phase change material or at least a portion thereof into an amorphous state.

Suitable phase change materials used for such phase change switches include germanium telluride (GeTe) or germanium-antimony-tellurium (GeSbTe, usually referred to as GST), and heaters may be made of a material like polycrystalline silicon or tungsten.

PCM switch devices promise excellent radio frequency performance in comparison to state of the art CMOS RF switches. In particular, the main figure of merit, the product of on-resistance and off capacitance, is reduced significantly from around 80 fsec for CMOS RF switches to values below 20fsec for PCM switch devices.

In particular, a low off capacitance is desirable in applications like antenna tuning, as resonant modes of tuning networks including such switches may adversely influence the antenna properties at a high operating frequency.

For example, when for tuning purposes such a PCM switch is coupled in series to an inductor having an inductance L, the off state capacitance CoFF of the switch creates a series resonance at a frequency

$${f}_{res} = \frac{1}{2 π \sqrt{{LC}_{OFF}}} .$$

This resonance frequency must be shifted to a value outside the operating frequency range of the respective system, for example radio frequency antenna, by either minimizing the inductance value L or minimizing C_{off}. The latter option is preferred, as it offers a higher degree of freedom in choosing the tuning elements, in particular inductances thereof, of a system.

### SUMMARY

A phase change material switch device as defined in claim 1 and a method as defined in claim 14 are provided. The dependent claims define further embodiments.

According to an embodiment, a phase change material switch device is provided, comprising: a phase change material, and a heater device thermally coupled to the phase change material.

The heater device is configured to: have a first electrical resistance in a first state where current is applied to the heater device for heating the phase change material, and have a second electrical resistance higher than the first electrical resistance in a second state outside heating phases of the heater device.

According to another embodiment, a method of operating a phase change material switch device is provided, the phase change material switch device comprising a phase change material and a heater device thermally coupled to the phase change material, the method comprising: switching a state of the phase change switch device by setting the heater device to a first state with a first electrical resistance and providing current through the heater device for heating the phase change material, and setting the heater device to a second state with a second electrical resistance higher than the first electrical resistance outside heating phases of the heater device.

The above summary is merely intended as a brief overview over some embodiments and is not to be construed as limiting in any way, as other embodiments may include different features from the ones listed above.

### BRIEF DESCRIPTION OF THE DRAWINGS

FIG. 1 is a block diagram of a phase change material switch device according to an embodiment.

FIG. 2A is a top view of a phase change material switch device used for comparison purposes, and FIG. 2B is a cross-sectional view thereof.

FIG. 3 is an equivalent circuit illustrating capacitances in the phase change material switch device of FIGS. 2A and 2B.

FIG. 4A is a top view of a phase change material switch device according to an embodiment, and FIG. 4B is a cross-sectional view thereof.

FIG. 5A is a top view of a phase change material switch device according to an embodiment, and FIG. 5B is a cross-sectional view thereof.

FIG. 6A is a top view of a phase change material switch device according to an embodiment, and FIG. 6B is a cross-sectional view thereof, and FIG. 6C illustrates controlling of a heater of the embodiments of FIGS. 5A, 5B, 6A or 6C.

FIG. 7A is a cross-sectional view of a phase change material switch device according to a further embodiment, and FIG. 7B illustrates heater control thereof.

FIG. 8 is a top view of a phase change material switch device for illustrating overlaps.

FIG. 9A is a first cross-sectional view of a phase change material switch device according to a further embodiment, and FIG. 9B is a second cross-sectional view thereof.

FIG. 10A is a first cross-sectional view of a phase change material switch device according to a further embodiment, and FIG. 10B is a second cross-sectional view thereof.

FIG. 11A is a first cross-sectional view of a phase change material switch device according to further embodiment, and FIG. 11B is a second cross-sectional view thereof.

FIG. 12A is a first cross-sectional view of a phase change material switch device according to an embodiment, and FIG. 12B is a second cross-sectional view thereof.

FIG. 13 is a cross-sectional view of a phase change material switch device according to a further embodiment.

FIG. 14 is a flow chart illustrating a method according to some embodiments.

FIG. 15 is a flow chart illustrating a method according to some embodiments.

FIG. 16 is a diagram illustrating an application environment for phase change material switch devices according to various embodiments.

### DETAILED DESCRIPTION

In the following, various embodiments will be described in detail referring to the attached drawings. The embodiments described hereinafter are to be taken as examples only and are not to be construed as limiting. For example, while in embodiments specific arrangements or components are provided, in other embodiments other configurations may be used.

Implementation details described with respect to one of the embodiments are also applicable to other embodiments.

Features from different embodiments may be combined to form further embodiments.

Variations and modifications described for one of the embodiments may also be applied to other embodiments and will therefore not be described repeatedly.

In the Figures, like elements are designated with the same reference numerals. Such elements will not be described repeatedly in each Figure to avoid repetitions. Any directional terminology used when referring to the drawings (e.g. up, down, left, right) is merely for indicating elements and directions in the drawings and is not intended to imply a directional orientation of the actually implemented devices.

Besides features (for example components, elements, acts, events or the like) explicitly shown and described, in other embodiments additional features may be provided, for example features used in conventional switch devices using phase change materials. For example, embodiments described herein relate to equalization devices in phase change material (PCM) switch devices, and other components and features, like spatial arrangement of heaters and phase change material, radio frequency (RF) circuitry using the switch device and the like may be implemented in a conventional manner. Such RF circuitry may be integrated with the described switch devices on the same substrate, but may also be provided separately for example, on one or more separate chip dies, which in some implementations then may be combined with a switch device in a common package. Also, manufacturing implementations like providing phase change material on a substrate like a silicon substrate to implement a PCM switch device or in a part thereof like a trench for manufacturing the switch device and the like may be performed in any conventional manner.

A switch based on a phase change material (PCM) will be referred to as a phase change switch (PCS) or PCM switch herein. As explained in the introductory portion, such phase change switches may be set to a crystalline phase state or an amorphous phase change, thus changing the resistance of the phase change material and therefore of the switch by several orders of magnitude. In this way, for example an on-resistance of a switch in a range of 1 to 100 Q may be achieved, whereas an off-resistance may be several orders of magnitude higher, for example at least in the Kiloohm range.

PCM switch devices discussed herein may be manufactured for example in layer deposition and pattering processes similar to those used in semiconductor device manufacturing, by depositing or modifying layers on a substrate. In some embodiments discussed herein, cross-sectional views and top views are illustrated. A cross-sectional view essentially corresponds to a cross section through the substrate, whereas a top view is a view in a direction towards a surface of the substrate.

While phase change switch devices in the embodiment below are shown with a configuration where a heater is provided below a phase change material, in other embodiments the heater may be provided above the phase change material. Furthermore, currents through the phase change material and through the heater may run in the same direction or in different, for example perpendicular directions. Therefore, the specific configurations shown are not to be construed as limiting in any way.

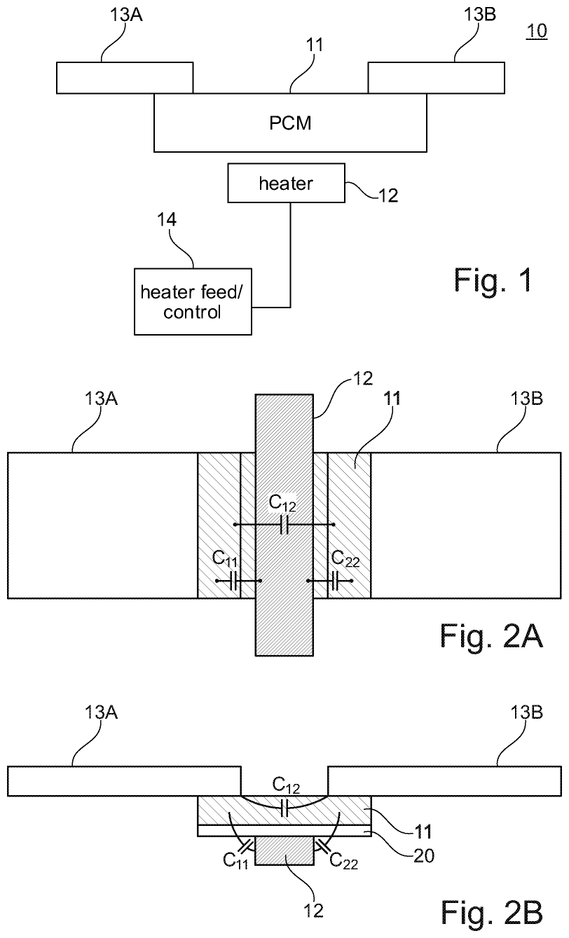

Turning now to the Figures, FIG. 1 illustrates a phase change material switch device, PCM switch device 10 according to an embodiment. PCM switch device 10 includes a phase change material 11, contacted by electrodes 13A, 13B. A heater 12 is placed adjacent to phase change material 11, electrically isolated but thermally coupled to phase change material 11. By heating phase change material 11 using heater 12, as in conventional PCM switch devices, phase change material 11 may be selectively set to a crystalline, electrically conducting state or to an amorphous, electrically isolating state. It should be noted that in the amorphous state phase change material 11 need not become fully amorphous, but some crystalline portions may remain for example in the vicinity of electrodes 13A, 13B, as long as the phase change material in the amorphous state provides an electrical isolation between electrodes 13A and 13B. Phase change material 11 may be any suitable phase change material described in the introductory portion.

Heater 12 is controlled and supplied with power by a heater feed/control entity 14. Heater 12, controlled by entity 14, may at least be in a first state or in a second state, which does not exclude further states being possible. In a first state, the heater has a first electrical resistance suitable for heating. This state, in other words, is used for heating phase change material 11 to perform a set or a reset operation as explained in the introductory portion, by feeding current through the heater. The first electrical resistance in the first state is such that heat is generated by dissipation of electrical power.

In the second state, heater 12 is configured to have a second electrical resistance higher than the first electrical resistance in the first state. For example, the first electrical resistance may be 500Ω or less, 100Ω or less or 50Ω or less and the second electrical resistance may be at least 100 times higher than the first electrical resistance, for example at least 500 times higher or about 1000 times higher, for example 10 kΩ or higher. Higher resistances like about 500Ω may for example occur in a hot state of the heater, where the heating increases the resistance. In some cases, in the second state the heater may be essentially electrically insulating. The second state may be used outside heating phases of the heater device, for example generally outside the heating phases or at least in a switched-off state of the PCM switch device 10. In some embodiments, this may reduce a parasitic capacitance between electrodes 13A, 13B and heater 12 in an off state of PCM switch device 10. This will now be explained in more detail referring to FIGS. 2A-2B, 3 and 4A-4B.

FIG. 2A shows a top view of a PCM switch device according to a comparative example, and FIG. 2B shows a cross-section thereof in a horizontal direction of FIG. 2A.

The PCM switch device of FIGS. 2A and 2B includes phase change material 11, electrodes 13A, 13B and heater 12 as already explained referring to FIG. 1. An electrically insulating but thermally conducting layer 20 is provided between heater 12 and phase change material 11 to provide thermal coupling and electric isolation.

In the comparative example of FIGS. 2A and 2B, heater 12 is a conventional heater which always has a comparatively low electrical resistance, for example below 50Ω, irrespective of a state the phase change switch device is in.

For an off state of the phase change switch device, parasitic capacitances are shown in FIGS. 2A and 2B. C₁₂ is a parasitic capacitance between first electrode 13A and second electrode 13B, C₁₁ is a parasitic capacitance between first electrode 13A or a part of phase change material 11 close to electrode 13A remaining electrically conducting and heater 12, and C₂₂ is a similar capacitance between electrode 13B or an electrically conducting portion of phase change material 11 adjacent to electrode 13B and heater 12. In other words, as heater 12 is electrically conducting also in the off state, it effectively acts as a capacitor plate. In case the switch is on and phase change material 11 is electrically conducting, still parasitic capacitances remain between phase change material 11 and heater 12, with layer 20 serving as electrically isolating layer therebetween.

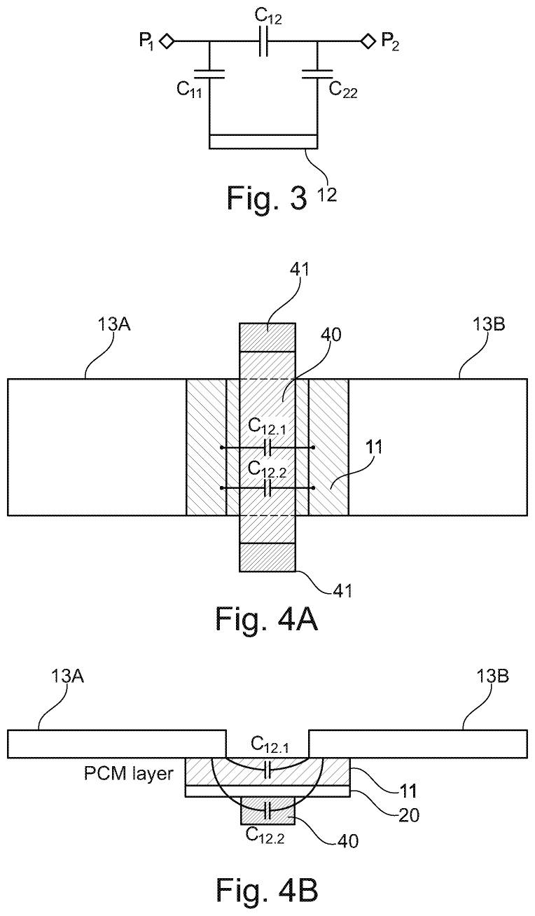

FIG. 3 shows an equivalent circuit illustrating the parasitic capacitances discussed above with respect to FIG. 2A and 2B in an equivalent circuit diagram. P₁ and P₂ are terminals corresponding to the first and second electrodes 13A, 13B, respectively.

As mentioned above, in some applications like antenna tuning applications, it is desirable to reduce the off capacitance as much as possible.

FIGS. 4A and 4B show a phase change device according to an embodiment in an off state, FIG. 4A showing a top view and FIG. 4B showing a cross-sectional view, similar to the comparative example of FIGS. 2A and 2B. Here, the heater is in the second state above, illustrated as having a high ohmic resistance(e.g. electrically insulating) portion 40 with electrical contact portions 41. This leads to a “replacement” of parasitic capacitances C₁₁, C₂₂ of FIGS. 2A, 2B and 3 with a capacitance C_{12,2} in parallel to the capacitance C₁₂ of FIGS. 2A, 2B and 3, which in FIGS. 4A and 4B is labelled C_{12,1}. C_{12,2} is lower than the series connection of C₁₁ and C₂₂ via heater 12 shown in FIGS. 2A, 2B and 3, such that the overall capacitance is lower.

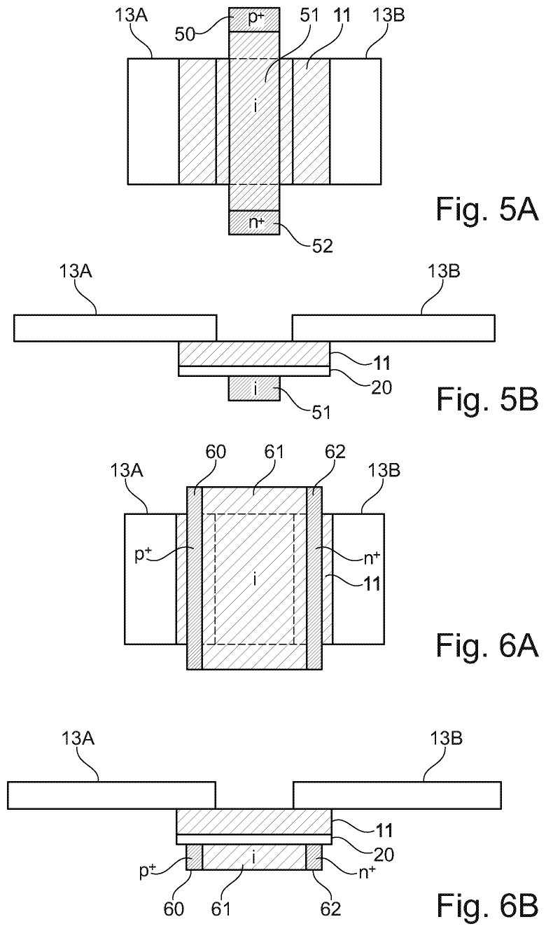

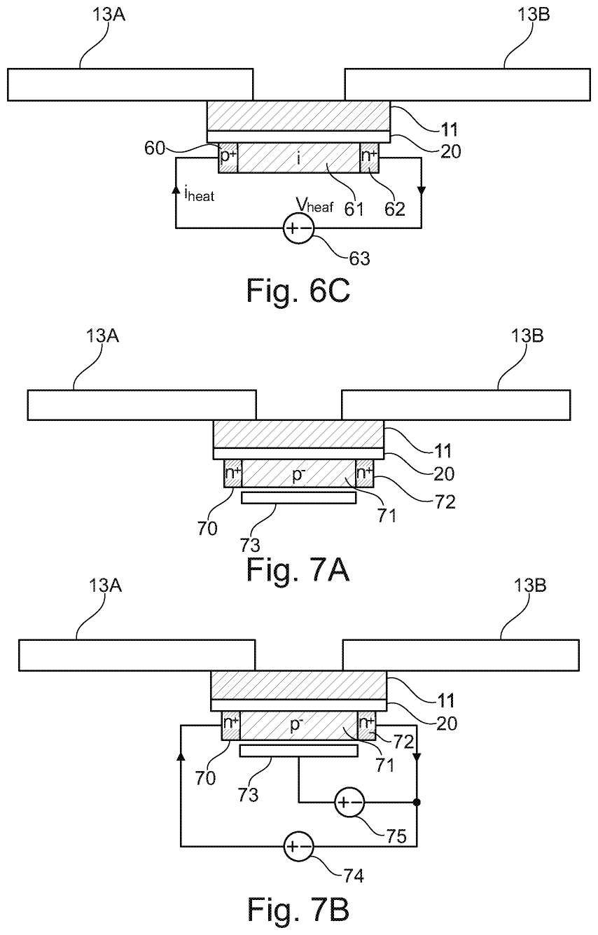

Next, various implementation examples of a heater that may change between the first state and the second state will be discussed. First, with reference to FIGS. 5A and 5B and FIGS. 6A to 6C, an implementation using a pin diode is shown.

FIG. 5A shows a top view of a PCM switch device according to an embodiment, and FIG. 5B shows a side view thereof. In the embodiment of FIGS. 5A and 5B, the heater is formed by a pin diode including a highly p-doped (p+) portion 50, a highly n-doped (n+) portion 52 and an intrinsic (i), i.e. nominally undoped or lightly doped, portion therebetween. Highly doped portions may have a resistivity smaller than 10Ω×cm or dopant concentrations greater than 1×10¹⁸/cm³, whereas lightly doped portions, for example the intrinsic portions above, may have a resistivity smaller than 100Ω×cm and a dopant concentration smaller than 1×10¹⁸/cm³, for example smaller than 1×10¹⁷/cm³.

In the top view of FIG. 5A, intrinsic portion 51 extends over the complete phase change material 11, and portions 50, 52 are outside the phase change material 11 in the top view. In the embodiment of FIGS. 5A and 5B, current flows through the phase change material 11 and therefore through the switch device in an on-state essentially from left to right in the view of FIGS. 5A and 5B, and through the heater from top to bottom in FIG. 5A or perpendicular to the drawing plane of FIG. 5B.

As will be further explained below referring to FIG. 6C, in the first state mentioned above, for heating of a phase change material 11 the pin diode 50, 51, 52 is forward biased above the threshold voltage, such that a current flows with relatively low resistance. In the second state mentioned above, i.e. outside heating, the pin diode is reversed bias, leading to a depletion portion essentially without free carriers and therefore correspondingly high ohmic resistance.

FIGS. 6A and 6B show a variation of the embodiment of FIGS. 5A and 5B. Also in case of FIGS. 6A and 6B, the heater is provided as a pin diode, here including a highly p-doped portion 60, an intrinsic portion 61 and a highly n-doped portion 62. In contrast to FIG. 5A and 5B, the orientation of the pin diode is rotated by 90° in the top view of FIGS. 6A, such that the current flow through the heater when heating phase change material 11 and the current flow through the phase change material from electrode 13A to 13B in an on-state are essentially in the same direction, from left to right in FIGS. 6A and 6B.

FIG. 6C shows an example control for the PCM switch device of FIGS. 6A and 6B. An adjustable voltage source 63 supplies the heater 60, 61, 62. For heating, as shown in FIG. 6 the pin diode forming the heater is forward biased, such that a heater flow iₕₑₐₜ flows, causing heat generation and heating of phase change material 11. Outside heating the polarity of voltage source 63 is reversed, such that the pin diode is reversed bias and a depletion portion is formed as explained above. Voltage source 63 in this case is an example for heater feed/control entity 14 of FIG. 1.

Heaters as used herein are not restricted to pin diodes. FIGS. 7A and 7B illustrate a device according to a further embodiment, where FIG. 7A illustrates a cross-section of the device, and FIG. 7B illustrates an example control of the heater of FIG. 7A.

In FIG. 7A, the heater is provided as an electrostatically controlled heater similar to a field effect transistor (FET), where the heater includes highly n-doped portions 70, 72 with a lightly p-doped portion 71 in between. In other embodiments, the polarity may be reversed, i.e. two p-doped portions with a n-doped portion in between. Furthermore, the heater includes a control electrode 73. This control electrode 73 operates similar to a gate electrode of a field effect transistor, and by applying an appropriate voltage to control electrode 73 as a control signal the resistance of the heater can be changed between the first and second states mentioned above.

It should be noted that also here, the heater may be provided rotated by 90° in a top view, as explained above with reference to FIGS. 5 and 6 for the pin diode.

FIG. 7B illustrates an example control. A first voltage/current source 74 is used to apply a heating current for heating the heater and therefore phase change material 11. A second voltage source 75 is configured to apply a control voltage to control electrode 73 with respect to p-doped portion 72, corresponding to applying an appropriate gate force voltage in conventional field effect transistors. By modifying the voltage, the heater may be set to a high ohmic state (second state above) outside heating phases or a low ohmic state (first state above) during heating. Voltage/Current source 74 and voltage source 75 are a further example for heater feed/control entity 13 of FIG. 1.

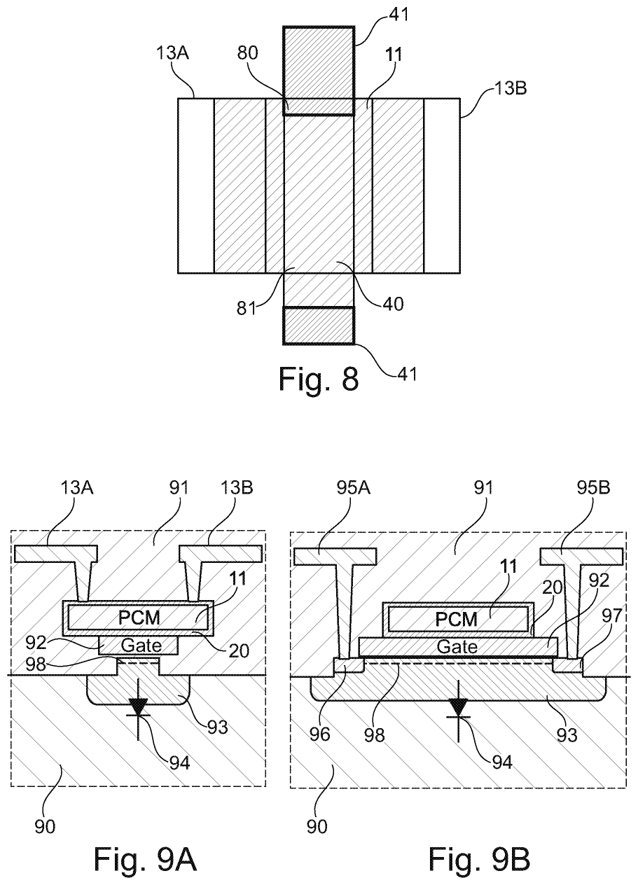

As already briefly mentioned for FIG. 5A, in the second state of the heater with the high resistance, in some embodiments the portion of the heater having the high resistance (depletion portion in case of a pin diode or also in case of the field effect transistor like arrangement in FIGS. 7A-7B, as well as for some embodiments described further below), overlaps with the phase change material in a top view, while electrically conducting portions like electrodes, highly doped portions or the like do not overlap with the phase change material, in order to further reduce the capacitance. This concept of overlap is further illustrated in FIG. 8.

FIG. 8 shows a heater corresponding to the heater of FIG. 4A, with an electrically isolating portion 40 which, in FIGS. 5 to 7 may correspond to the intrinsic portion in case of the pin diode or the lightly p doped portion for the field effect transistor like implementation, and conducting portions 41 correspond to the highly p- or n-doped portions. In the top view of FIG. 8, at 80 an overlap exists between the top electrode 41 and phase change material 11, or at least with portions of the phase change material that are turned amorphous in the switched off state, whereas for the lower electrode 41, at 81, no overlap exists. As mentioned above, in some embodiments such an overlap is avoided altogether avoided (as explained e.g. for FIGS. 5A and 5B) to further decrease the parasitic capacitance. It should be noted in the rotated arrangement of FIGS. 6A and 6B, electrode 41 may e.g. overlap with electrode 13A, 13B in the top view.

In FIGS. 7A and 7B, a field effect transistor like heater was illustrated. Further configurations of field effect transistors usable as heaters, as well as contacting thereof, will now be described referring to FIGS. 9A through 13. FIGS. 9A, 10A, 11A and 12A in each case show a cross-sectional view in a first direction, and FIGS. 9B, 10B, 11B and 12B in each case show a cross-sectional view in a second direction perpendicular to the first direction. For example, given the top views discussed previously, FIGS. 9A, 10A, 11A and 12A may be a cross-section from left to right in the top view, and FIGS. 9B, 10B, 11B and 12B may be a cross-section from top to bottom of the top view.

FIGS. 9A and 9B show an embodiment of a PCM switch device having a field effect transistor as a heater. The PCM switch device of FIGS. 9A-9B is formed on a substrate 90, for example a lightly n-doped semiconductor substrate. A p-doped portion 93 is formed in substrate 90. N-doped source and drain portions 96, 97 are also formed. Separated from portion 93 by a gate oxide, a gate electrode 92 is formed, for example made of metal or polysilicon. Separated from gate electrode 92 by electrically insulating but thermally conducting material 20, the phase change material 11 is deposited. Electrodes 13A, 13B are formed for contacting phase change material 11, and electrodes 95A, 95B are formed for contacting source and drain portions 96, 97, respectively. An additional electrode (not shown in FIGS. 9A and 9B) is formed for electrically contacting the gate electrode 92. The structure is enclosed in a dielectric material 91, for example silicone dioxide. Formation of the structure of FIGS. 9A and 9B, as with previously discussed PCM devices, may use conventional semiconductor process techniques for depositing the various components in layers (for example the electrodes in metal layers), and/or using doping techniques like diffusion doping or ion implantation to form the portion.

In the first state, for heating the phase change material, electrode 92 is controlled such that an n channel indicated by a dashed line 98 is formed through which current can flow from electrode 95A to electrode 95B, causing heat generation and heating of phase change material 11.

In the second state outside the heating, the gate may be controlled to cause a high electric resistance between source and drain terminals 96, 97. In some embodiments, the transistor may be a normally off transistor, such that when no voltage is applied the gate electrode, the transistor is in an off state corresponding to the second state having a high resistance.

Reference numeral 94 illustrates a parasitic body diode of the transistor, formed between p-doped portion 93 and substrate 90.

FIGS. 10A and 10B illustrate a variation of the embodiment of FIGS. 9A-9B. FIG. 10A shows a cross-sectional view corresponding to the view of FIG. 9A, and FIG. 10B shows a cross-sectional view corresponding to the cross-sectional view of FIG. 9B.

Compared to the embodiment of FIGS. 9A and 9B, as best seen in FIG. 10B the source and drain terminals are modified and include highly n-doped portions 1001, 1002, respectively, and lower doped n-type doped portions 1003, 1004 having a thin somewhat L-shaped shape in cross-section as shown in FIG. 10B. Portions 1003, 1004 may have a similar doping as substrate 90 or may in part B made of substrate 90 in a manufacturing process. The configuration of FIGS. 10A-10B compared to the configuration of Fi. 9, may lead to a higher voltage capability of the source and drain terminals versus the gate terminals, i.e. higher voltages may be applied to the PCM switch device for example in an off state.

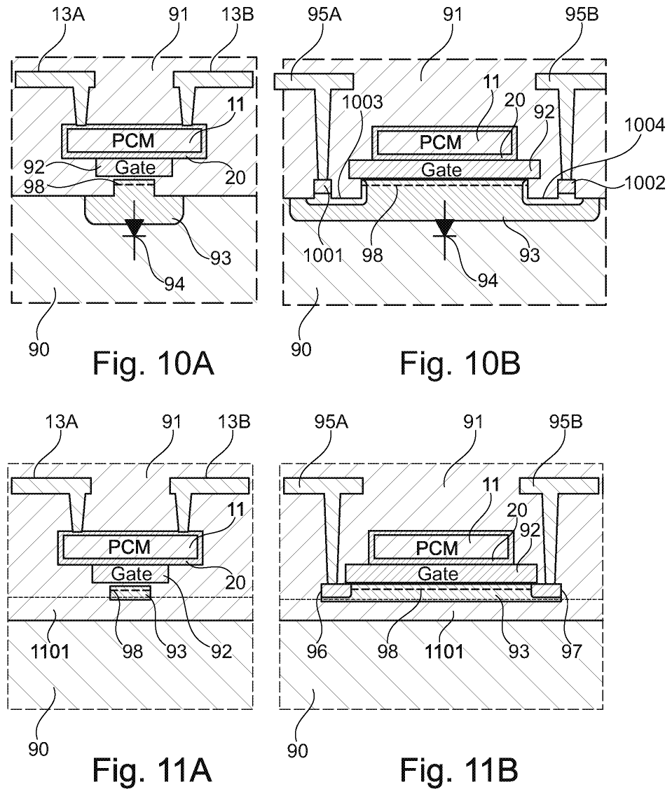

FIGS. 11A and 11B illustrate a further modification of the embodiment of FIGS. 9A-9B, where FIG. 11A shows a cross-sectional view corresponding to FIG. 9A and FIG. 11B shows a cross-sectional view corresponding to FIG. 9B. Here, instead of a normal substrate like a normal silicone substrate 90 a silicon on insulator (SOI) substrate is used, including substrate 90 and silicon dioxide layer 1102. The devices are then formed on a silicon layer (as a layer not shown in FIGS. 11A and 11B, or removed during the processing) on top of silicon dioxide layer 1101. In this case no bulk diode 94 is formed, which in some cases may improve the high frequency behavior of the switch device.

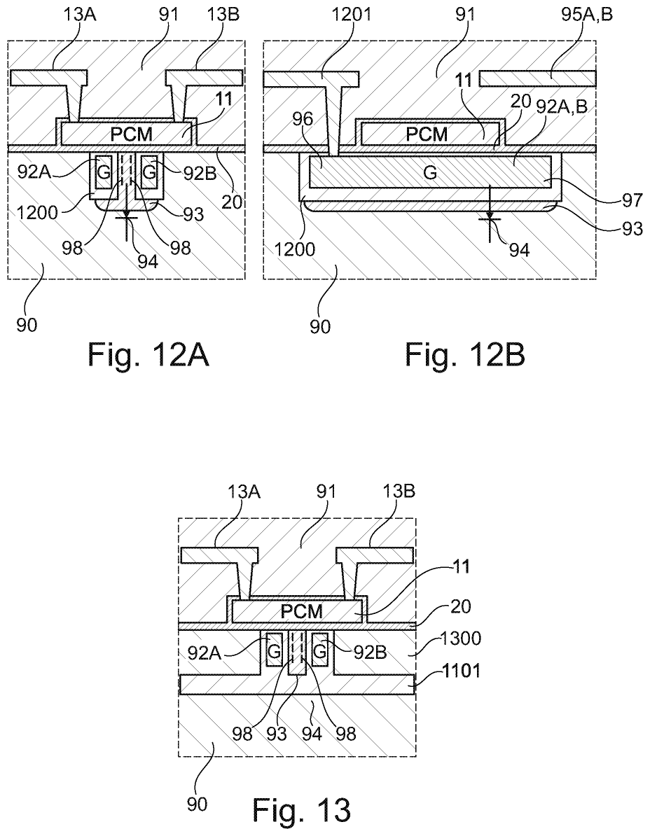

The embodiments of FIGS. 9A to 11B show planar field effect transistor devices. In other embodiments, as a heater a field effect transistor may be provided in a trench within a substrate. Corresponding embodiments will now be described referring to FIGS. 12A-12B and 13.

In FIGS. 12A and 12B, a trench field effect transistor is provided in a trench formed in substrate 90. Gate electrodes 92A, 92B in the cross-section of FIG. 12A are formed on two sides of p-doped portion 93, leading to the formation of two n-channels in a switched on state for heating as indicated by dashed lines 98. Current trough the heater flows in a horizontal direction in the view of FIG. 12B or perpendicular to the drawing plane of FIG. 12A. Electrodes 1201, of which one is shown in FIG. 12B, contact gate electrodes 92A, 92B, and electrodes 95A, 95B as schematically shown contact source and drain portions, which are not explicitly shown in FIGS. 12A and 12B. With the arrangement in a trench, the gate electrode is not interposed between the phase change material and the N-channel when heating. Simulations have shown that this may lead to an advantageous heat distribution from heating phase change material 11.

FIG. 13 illustrates a variation of the embodiment of FIGS. 12A-12B provided on a silicon on insulator substrate including the bulk substrate 90, silicon dioxide layer 1101 and a silicon layer 1300 on top of silicon dioxide layer 1101.

The field effect transistor is provided in a trench within layer 1300. Otherwise, the configuration corresponds to the configuration of the trench transistor of FIGS. 12A-12B. Similar to FIGS. 11A-11B, also here no bulk diode is present.

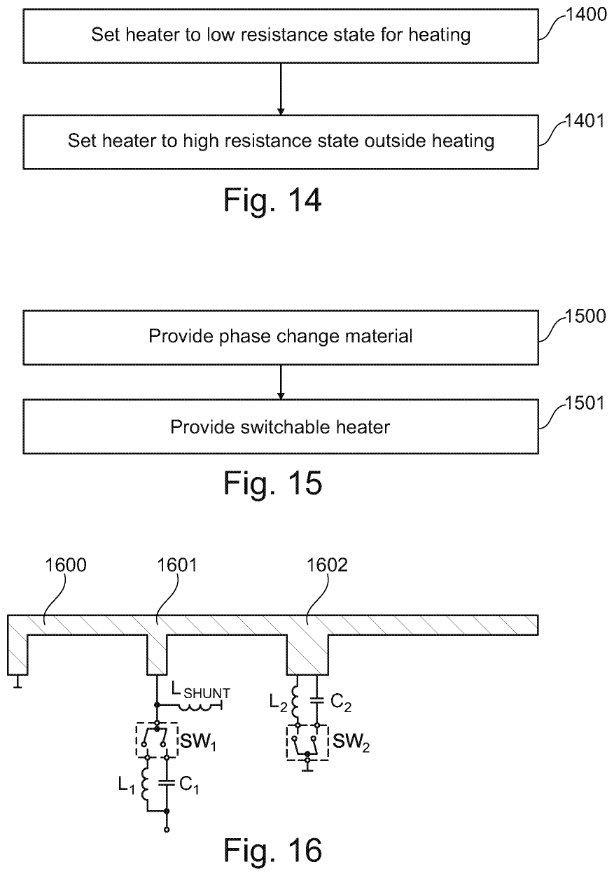

FIG. 14 is a flow chart illustrating a method according to an embodiment, which may be used for operating the PCM switch devices of any of the preceding embodiments. To avoid repetitions, the method of FIG. 14 will be described referring to those embodiments.

At 1400, the method comprises setting a heater of a PCM switch device to a low first state having a low electrical resistance for heating the phase change material, in order to perform a set of reset operation. For example, in case the heater is provided as a pin diode, the diode may be forward biased, and when it is provided as a transistor-like structure, a control electrode may be controlled accordingly.

At 1401, the method comprises setting the heater to a high resistance second state having a high electrical resistance outside the heating, for example in an off state, on state or both. For example, in case of a pin diode this diode may be reversed biased, or a control electrode of a transistor-like structure may be controlled such that no conductive channel is formed.

The actions at 1400 and 1401 may be repeated in any order. For example, the heater may be set to the first, low resistance state at 1004 any time a set or reset operation and therefore a heating of the phase change material is to be performed.

FIG. 15 is a flow chart illustrating a method for manufacturing a PCM switch device according to an embodiment, for example for manufacturing any of the embodiments discussed above. Again, the method will be described referring to the previous Figures.

At 1500 the method comprises providing a phase change material. At 1501, the method comprises providing a heater which is switchable between a first state and a second state as explained above in thermal contact with the phase change material. It should be noted that the order of 1500 and 1501 may also be reversed such that the heater is first manufactured, followed by the phase change material. For example, in the embodiments discussed above, heater structures may first be formed by deposition, iron implantation and the like, and then the phase change material may be deposited.

FIG. 16 illustrates an application example of PCM switch devices according to embodiments for antenna tuning purposes. FIG. 16 illustrates an antenna structure 1600 including a so called feed point 1601 and a first aperture point 1602. Feed point 1601 is coupled to a shunt inductor Lₛₕᵤₙₜ and, for tuning purposes, may be selectively coupled via a first switch device SW₁ with a parallel circuit of an inductor L₁ and a capacitor C₁. Aperture point 1602 is coupled to an inductor L₂ and a capacitor C₂ as shown, which may be selectively coupled to ground via a switch device SW₂. Switch devices SW₁, SW₂ in an embodiment are implemented using PCM switch devices according to any of the above embodiments. In this way, a parasitic capacitance of switches SW₁, SW₂ is reduced, which otherwise could adversely affect the tuning behavior and radio frequency behavior.

Some embodiments may be defined by the following examples:

Example 1. A phase change material switch device, comprising: a phase change material, and a heater device thermally coupled to the phase change material, wherein the heater device is configured to: have a first electrical resistance in a first state where current is applied to the heater device for heating the phase change material, and have a second electrical resistance higher than the first electrical resistance in a second state outside heating phases of the heater device.

Example 2. The phase change material switch device of example 1, wherein the second electrical resistance is at least 100 times higher than the first electrical resistance.

Example 3. The phase change material switch device of example 1 or 2, wherein the first electrical resistance is 500 Ohm or less.

Example 4. The phase change material switch device of any one of example 1 to 3, wherein the second electrical resistance is 1 Kiloohm or higher.

Example 5. The phase change switch device of any one of examples 1 to 4, further comprising at least one electrical conductor galvanically coupled to the phase change material, wherein a capacitance caused by the heater device is lower in the second state than in the first state.

Example 6. The phase change material switch device of any one of example 1 to 5, further comprising an electrically insulating material between the heater device and the phase change material.

Example 7. The phase change material switch device of any one of examples 1 to 6, wherein the heater device includes a semiconductor device configured to cause the first state and the second state.

Example 8. The phase change material switch device of example 7, wherein the semiconductor device includes a pin diode, wherein the pin diode is forward biased in the first state and reverse biased in the second state.

Example 9. The phase change material switch device of example 7 or 8, wherein the semiconductor device comprises a lightly doped or intrinsic semiconductor material provided in thermal contact with the heater device and at least one heavily doped semiconductor or metal region in contact with the lightly doped or intrinsic semiconductor material.

Example 10. The phase change material switch device of example 7, wherein the semiconductor device comprises a transistor, which is configured to be set to a switched off state in the second state.

Example 11. The phase change material switch device of example 10, wherein the transistor comprises a MOSFET.

Example 12. The phase change material switch device of example 10 or 11, wherein the transistor comprises a transistor provided at least partially in a trench.

Example 13. The phase change switch device of any one of examples 1 to 12, wherein in a top view a part causing the second electrical resistance in the second state partially covers the same area as the phase change material, and contact regions adjacent to the part with lower resistance are outside an area covered by an amorphous region of the phase change material in a switched off state of the phase change material switch device and/or in a same area as at least one electrical conductor galvanically coupled to the phase change material.

Example 14. A method of operating a phase change material switch device, the phase change material switch device comprising a phase change material, and a heater device thermally coupled to the phase change material, the method comprising: switching a state of the phase change material switch device by setting the heater device to a first state with a first electrical resistance and providing current through the heater device for heating the phase change material, and setting the heater device to a second state with a second electrical resistance higher than the first electrical resistance outside heating phases of the heater device.

Example 15. The method of example 14, further comprising switching a radio frequency signal to the phase change material switch device.

Example 16. The method of example 14 or 15, wherein the heater device include a pin diode, wherein the method comprises forward biasing the pin diode in the first state, and reverse biasing the pin diode in the second state.

Example 17. The method of example 14 or 15, wherein the heater device include a field effect transistor including a control electrode, wherein the method comprises setting the heater device to the first or second state by applying a control signal to the control electrode.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A phase change material switch device, comprising:
a phase change material; and
a heater device thermally coupled to the phase change material,
wherein the heater device is configured to:
have a first electrical resistance in a first state where current is applied to the heater device for heating the phase change material; and
have a second electrical resistance higher than the first electrical resistance in a second state outside heating phases of the heater device.

2. The phase change material switch device of claim 1, wherein the second electrical resistance is at least 100 times higher than the first electrical resistance.

3. The phase change material switch device of claim 1, wherein the first electrical resistance is 500 Ohm or less.

4. The phase change material switch device of claim 1, wherein the second electrical resistance is 1 Kiloohm or higher.

5. The phase change material switch device of claim 1, further comprising at least one electrical conductor galvanically coupled to the phase change material, wherein a capacitance caused by the heater device is lower in the second state than in the first state.

6. The phase change material switch device of claim 1, further comprising an electrically insulating material between the heater device and the phase change material.

7. The phase change material switch device of claim 1, wherein the heater device includes a semiconductor device configured to cause the first state and the second state.

8. The phase change material switch device of claim 7, wherein the semiconductor device includes a pin diode, and wherein the pin diode is forward biased in the first state and reverse biased in the second state.

9. The phase change material switch device of claim 7, wherein the semiconductor device comprises a lightly doped or intrinsic semiconductor material provided in thermal contact with the heater device and at least one heavily doped semiconductor or metal region in contact with the lightly doped or intrinsic semiconductor material.

10. The phase change material switch device of claim 7, wherein the semiconductor device comprises a transistor configured to be set to a switched off state in the second state.

11. The phase change material switch device of claim 10, wherein the transistor comprises a MOSFET.

12. The phase change material switch device of claim 10, wherein the transistor comprises a transistor provided at least partially in a trench.

13. The phase change switch device of claim 1, wherein in a top view, a part causing the second electrical resistance in the second state partially covers the same area as the phase change material, and contact regions adjacent to the part with lower resistance are outside an area covered by an amorphous region of the phase change material in a switched off state of the phase change material switch device and/or in a same area as at least one electrical conductor galvanically coupled to the phase change material.

14. A method of operating a phase change material switch device that includes a phase change material and a heater device thermally coupled to the phase change material, the method comprising:
switching a state of the phase change material switch device by setting the heater device to a first state with a first electrical resistance and providing current through the heater device for heating the phase change material; and
setting the heater device to a second state with a second electrical resistance higher than the first electrical resistance outside heating phases of the heater device.

15. The method of claim 14, further comprising switching a radio frequency signal to the phase change material switch device.
